(19) United States
(12) Patent Application Publication
(10) Pub. No.: US 2024/0063811 A1
(43) Pub. Date: Feb. 22, 2024

(54) SUCCESSIVE-APPROXIMATION TYPE A/D CONVERSION CIRCUIT

(71) Applicant: ROHM CO., LTD., Kyoto (JP)

(72) Inventor: Harumi GO, Kyoto (JP)

(21) Appl. No.: 18/452,702

(22) Filed: Aug. 21, 2023

(30) Foreign Application Priority Data
Aug. 22, 2022 (JP) 2022-131664

(51) Int. Cl. H03M 1/18; H03M 1/38

(52) U.S. Cl. CPC H03M 1/182; H03M 1/38

(57) ABSTRACT

A successive-approximation type A/D conversion circuit includes: a selection signal input terminal that receives a selection signal; a clock input terminal that receives a clock signal; a main circuit that generates digital data in synchronization with the clock signal during an active period; a data output terminal; a data output circuit that outputs the digital data as a serial signal from the data output terminal during the active period; and a level adjustment circuit. The data output circuit outputs the serial signal by setting a signal level of the data output terminal to a first level and setting the signal level to the first level or a second level during the active period. When the signal level has the second level at the time of switching from the active period to a non-active period, the level adjustment circuit changes the signal level from the second level to the first level.

### CROSS-REFERENCE TO RELATED APPLICATION

This application is based upon and claims the benefit of priority from Japanese Patent Application No. 2022-131664, filed on Aug. 22, 2022, the entire contents of which are incorporated herein by reference.

### TECHNICAL FIELD

The present disclosure relates to a successive-approximation type A/D conversion circuit.

### BACKGROUND

As an A/D conversion circuit that converts analog signals into digital data, a successive-approximation type A/D conversion circuit is known. A certain type of successive-approximation type A/D conversion circuit performs A/D conversion when a selection signal, which is also called a chip select signal, is active, and outputs the obtained digital data as a serial signal from a data output terminal.

### BRIEF DESCRIPTION OF DRAWINGS

The accompanying drawings, which are incorporated in and constitute a part of the specification, illustrate embodiments of the present disclosure.

FIG. 1 is a configuration diagram of an A/D conversion system according to an embodiment of the present disclosure.

FIG. 2 is an external perspective view of an A/D converter according to the embodiment of the present disclosure.

FIG. 3 is a structural diagram of digital data generated by the A/D converter according to the embodiment of the present disclosure.

FIG. 4 is a diagram showing a relationship between some signals and an output-stage circuit according to the embodiment of the present disclosure.

FIG. 5 is a timing chart of a virtual operation.

FIG. 6 is a diagram showing signal ringing that may occur in the virtual operation.

FIG. 7 is a diagram showing one aspect of a level adjustment circuit (corresponding to a first output specification) according to the embodiment of the present disclosure.

FIG. 8 is a diagram showing another aspect of the level adjustment circuit (corresponding to a second output specification) according to the embodiment of the present disclosure.

FIG. 9 is a circuit diagram of a data output circuit including an internal configuration of a level adjustment circuit according to Example EX_A1 belonging to the embodiment of the present disclosure.

FIG. 10 is a schematic waveform diagram of a selection signal and a data signal according to Example EX_A1 belonging to the embodiment of the present disclosure.

FIG. 11 is a circuit diagram of a data output circuit including an internal configuration of a level adjustment circuit according to Example EX_A2 belonging to the embodiment of the present disclosure.

FIG. 12 is a circuit diagram of a data output circuit including an internal configuration of a level adjustment circuit according to Example EX_A3 belonging to the embodiment of the present disclosure.

FIG. 13 is a timing chart related to a plurality of signals according to Example EX_A3 belonging to the embodiment of the present disclosure.

FIG. 14 is a schematic waveform diagram of a selection signal and a data signal according to Example EX_A3 belonging to the embodiment of the present disclosure.

FIG. 15 is a circuit diagram of a data output circuit including an internal configuration of a level adjustment circuit according to Example EX_B1 belonging to the embodiment of the present disclosure.

FIG. 16 is a schematic waveform diagram of a selection signal and a data signal according to Example EX_B1 belonging to the embodiment of the present disclosure.

FIG. 17 is a circuit diagram of a data output circuit including an internal configuration of a level adjustment circuit according to Example EX_B2 belonging to the embodiment of the present disclosure.

FIG. 18 is a circuit diagram of a data output circuit including an internal configuration of a level adjustment circuit according to Example EX_B3 belonging to the embodiment of the present disclosure.

FIG. 19 is a timing chart related to a plurality of signals according to Example EX_B3 belonging to the embodiment of the present disclosure.

FIG. 20 is a schematic waveform diagram of a selection signal and a data signal according to Example EX_B3 belonging to the embodiment of the present disclosure.

### DETAILED DESCRIPTION

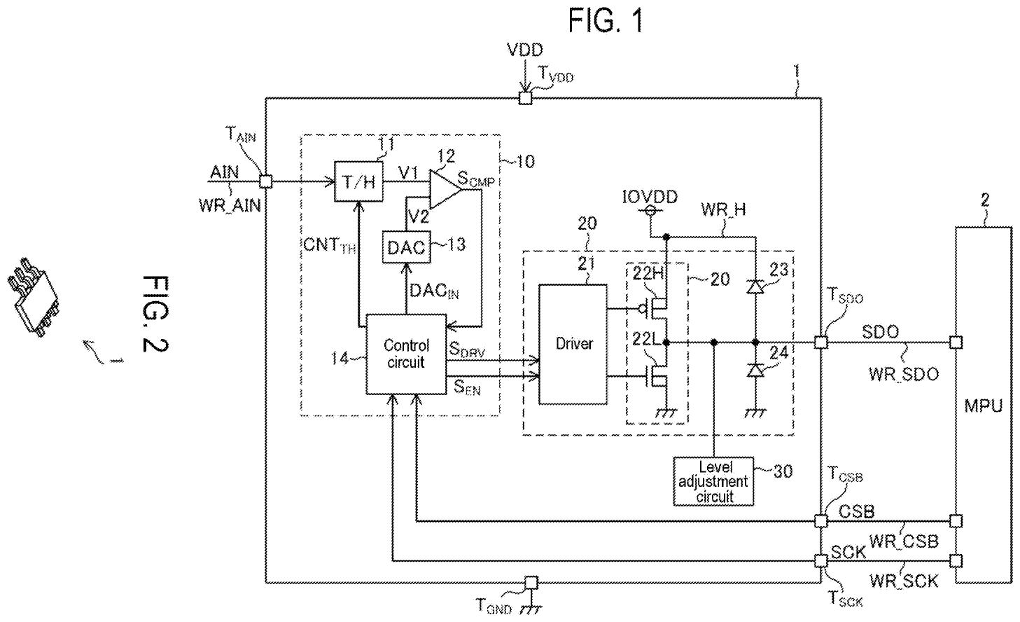

Examples of embodiments of the present disclosure will be specifically described below in detail with reference to the drawings. Throughout the referred drawings, the same parts are denoted by the same reference numerals, and duplicate explanation thereof will not be repeated in principle. In this specification, for the sake of simplification in description, by describing a symbol or a code that refers to information, a signal, a physical quantity, a functional part, a circuit, an element, parts, or the like, the information, the signal, the physical quantity, the functional part, the circuit, the element, the parts, or the like, corresponding to the symbol or the code may be omitted or abbreviated. For example, an analog signal referred to by “AIN” to be described later (see FIG. 1) may be written as an analog signal AIN or abbreviated as a signal AIN, all of which refer to the same thing.

First, some terms used in the description of the embodiments of the present disclosure will be described. A ground refers to a reference conductive portion having a reference potential of 0 V (zero volts) or refers to the potential of 0 V itself. A reference conductive portion may be formed of a conductor such as metal. A potential of 0 V may be referred to as a ground potential. In the embodiments of the present disclosure, a voltage shown without any particular reference represents a potential seen from the ground.

A level refers to a level of potential, with a high level having a higher potential than a low level for any signal or voltage of interest. For any signal or voltage of interest, strictly speaking, a signal or voltage being at a high level means that the level of the signal or voltage is a high level, and strictly speaking, a signal or voltage being at a low level means that the level of the signal or voltage is a low level. The level for a signal is sometimes expressed as a signal level, and the level for a voltage is sometimes expressed as a voltage level.

For any signal or voltage of interest, switching from a low level to a high level is called an up-edge, and a timing of switching from a low level to a high level is called an up-edge timing. The up-edge may be read as a rising edge. Similarly, for any signal or voltage of interest, switching from a high level to a low level is called a down-edge, and a timing of switching from a high level to a low level is called a down-edge timing. The down-edge may be read as a falling edge.

For any transistor configured as a FET (Field Effect Transistor), including a MOSFET, a turn-on state refers to a state in which the drain and source of the transistor are electrically conductive with each other, and a turn-off state refers to a state in which the drain and source of the transistor are electrically non-conductive with each other (cut-off state). The same applies to transistors that are not classified as FETs. Unless otherwise specified, a MOSFET is regarded as an enhancement type MOSFET. MOSFET is an abbreviation for “Metal-Oxide-Semiconductor Field-Effect Transistor.” Further, unless otherwise specified, it may be considered that the back gate is short-circuited to the source in any MOSFET. Hereinafter, for any transistor, a turn-on state and a turn-off state may be simply expressed as on and off, respectively.

A connection between a plurality of parts forming a circuit, such as arbitrary circuit elements, wirings, and nodes, may be understood to refer to an electrical connection unless otherwise specified.

FIG. 1 shows a configuration diagram of an A/D conversion system according to an embodiment of the present disclosure. The A/D conversion system in FIG. 1 includes an A/D converter 1 and an MPU 2 (Micro Processing Unit). The A/D converter 1 is a successive-approximation type A/D conversion circuit. An analog signal AIN is input to the A/D converter 1. The A/D converter 1 performs an A/D conversion operation on the analog signal AIN. In the A/D conversion operation, the analog signal AIN is converted into digital data DOUT by binary search, and the obtained digital data DOUT is output bit by bit as a serial signal from a data output terminal T_{SDO} which will be described later. Further, it is to be noted that the digital data DOUT is not shown in FIG. 1. The digital data may be read as a digital signal.

FIG. 2 is an external perspective view of the A/D converter 1. The A/D converter 1 is an electronic component including a semiconductor chip having a semiconductor integrated circuit formed on a semiconductor substrate, a housing (package) accommodating the semiconductor chip, and a plurality of external terminals exposed from the housing to the outside of the A/D converter 1. The A/D converter 1 is formed by enclosing the semiconductor chip in the housing (package) made of resin. Terminals T_{VDD}, T_{GND}, T_{AIN}, T_{SDO}, T_{CSB}, and T_{SCK} included in the plurality of external terminals are shown in FIG. 1. External terminals other than these may also be provided in the A/D converter 1. Further, the number of external terminals of the A/D converter 1 and the type of the housing of the A/D converter 1 shown in FIG. 2 are merely examples, and they may be designed arbitrarily.

The terminal T_{VDD} is a power supply terminal. A power supply voltage VDD is supplied from a voltage source (not shown) to the power supply terminal T_{VDD}. The power supply voltage VDD is a positive DC voltage. Each circuit in the A/D converter 1 is driven based on the power supply voltage VDD. The A/D converter 1 may be provided with an internal power supply circuit that generates an internal power supply voltage, which is another DC voltage, from the power supply voltage VDD. Some circuits in the A/D converter 1 may be driven based on the internal power supply voltage. The terminal T_{GND} is a ground terminal. The ground terminal T_{GND} is connected to the ground.

The terminal T_{AIN} is an analog input terminal. The analog input terminal T_{AIN} is connected to a wiring WR_AIN provided outside the A/D converter 1. The analog signal AIN is applied to the wiring WR_AIN. The analog signal AIN propagating through the wiring WR_AIN is input to the analog input terminal TAN.

The terminals T_{SDO}, T_{CSB}, and T_{SCK} are a data output terminal, a selection signal input terminal, and a clock input terminal, respectively. The terminals T_{SDO}, T_{CSB}, and T_{SCK} are connected to one ends of wirings WR_SDO, WR_CSB, and WR_SCK, respectively. Other ends of the wirings WR_SDO, WR_CSB, and WR_SCK are connected to the MPU 2. That is, the A/D converter 1 and the MPU 2 are connected to each other via the wirings WR_SDO, WR_CSB, and WR_SCK.

A signal applied to the terminal T_{SDO} and the wiring WR_SDO is called a data signal SDO. A signal applied to the terminal T_{CSB} and the wiring WR_CSB is called a selection signal CSB. A signal applied to the terminal T_{SCK} and the wiring WR_SCK is called a clock signal SCK. The selection signal CSB is generally called a chip select signal, and the terminal T_{CSB} is generally called a chip select terminal.

The data signal SDO is output from the A/D converter 1 and is received by the MPU 2. The selection signal CSB and the clock signal SCK are output from the MPU 2 and are received by the A/D converter 1.

The signals SDO, CSB, and SCK are binary signals that take a signal level of high level or low level. The high level in the signals SDO, CSB, and SCK has the potential of a power supply voltage IOVDD for communication. The low level in the signals SDO, CSB, and SCK has the ground potential. The power supply voltage IOVDD is a positive DC voltage. The high level in the signals SDO, CSB, and SCK may be slightly lower than the potential of the power supply voltage IOVDD, and the low level in the signals SDO, CSB, and SCK may be slightly higher than the ground potential. However, the high level in the signals SDO, CSB, and SCK is higher than at least a predetermined high-side threshold voltage V_{H}, and the low level in the signals SDO, CSB, and SCK is lower than at least a predetermined low-side threshold voltage V_{L}. Here, the relationship of “IOVDD>V_{H}>IOVDD/2>V_{L}>0” is established. The power supply voltage IOVDD for communication may be the same as the power supply voltage VDD, or may be different from the power supply voltage VDD. In the following, it is considered that “IOVDD=VDD.”

The selection signal CSB becomes active or non-active depending on the level of the selection signal CSB. When the selection signal CSB has an active level, the selection signal CSB is active, and when the selection signal CSB has a non-active level, the selection signal CSB is non-active. A period during which the selection signal CSB has the active level is called an active period, and a period during which the selection signal CSB has the non-active level is called a non-active period. In this embodiment, it is assumed that negative logic is adopted for the selection signal CSB. That is, it is assumed that the active level of the selection signal CSB is a low level and the non-active level of the selection signal CSB is a high level.

The A/D converter 1 is also active during the active period. The A/D converter 1 performs the A/D conversion operation and outputs the data signal SDO representing the digital data DOUT only during the active period. The clock signal SCK becomes a significant signal only during the active period, and the A/D conversion operation and the output of the data signal SDO are performed in synchronization with the clock signal SCK.

The A/D converter 1 includes, as main components, a main circuit 10, a data output circuit 20, and a level adjustment circuit 30. The main circuit 10 is connected to the terminals T_{AIN}, T_{CSB}, and T_{SCK} and receives the signals AIN, CSB, and SCK. In the active period, the main circuit 10 performs the A/D conversion operation in synchronization with the clock signal SCK to generate the digital data DOUT representing the A/D conversion result for the analog signal AIN.

The digital data DOUT is N-bit digital data. That is, the digital data DOUT has a total of N bits from the first bit to the N-th bit. N is any integer of 2 or more, for example, 8, 10, 12, 14, or 16. Here, it is assumed that the (i+1)-th bit is the upper bit when viewed from the i-th bit. Therefore, among the first to N-th bits, the first bit is the least significant bit and the N-th bit is the most significant bit. i represents an arbitrary integer.

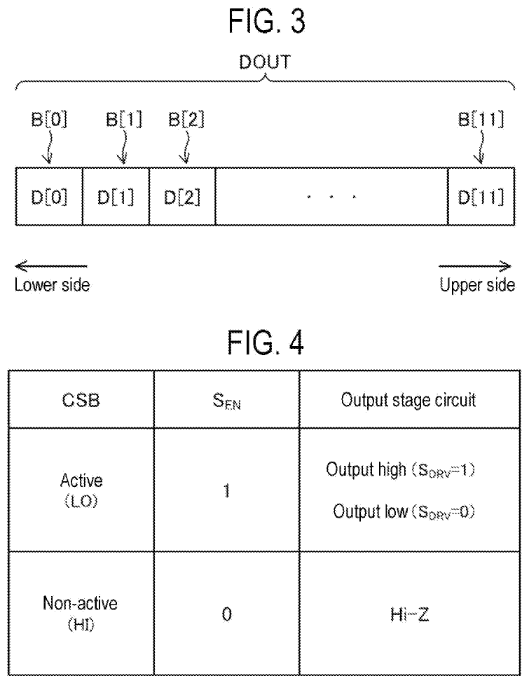

In this embodiment, hereinafter, a case of “N=12” will be taken as an example for the purpose of concrete description. FIG. 3 shows a structure of the digital data DOUT. The first to N-th bits in the digital data DOUT are represented by B[0] to B [N−1], respectively. Each bit in the digital data DOUT has a value of “1” or “0.” A value of bit B[i] is represented by a symbol “D[i].” A value D[i] is sometimes referred to as a bit value.

In the configuration example of FIG. 1, the main circuit 10 includes a track/hold circuit 11 (hereinafter referred to as a T/H circuit 11), a comparator 12, a DAC 13, and a control circuit 14.

The T/H circuit 11 is connected to the analog input terminal T_{AIN} and receives the analog signal AIN. The T/H circuit 11 operates in a track mode or a hold mode based on a control signal CNT TH from the control circuit 14 and outputs a signal V1 based on the analog signal AIN. The control signal CNT TH is a binary signal having “0” or “1.” When the control signal CNT_{TH} has a value of “0,” the T/H circuit 11 operates in the track mode, and when the control signal CNT_{TH} has a value of “1,” the T/H circuit 11 operates in the hold mode.

In the track mode, the T/H circuit 11 outputs the signal V1 having the same potential as the analog signal AIN in real time. When the control signal CNT TH switches from “0” to “1,” the T/H circuit 11 holds the analog signal AIN at the switching timing and continuously outputs the held analog signal AIN as the signal V1 in the hold mode.

The comparator 12 compares the signal V1 from the T/H circuit 11 and a signal V2 from the DAC 13, and outputs a signal S_{CMP} indicating the comparison result (that is, the potential level relationship between the signals V1 and V2).

The DAC 13 is an N-bit digital/analog converter. N-bit digital data DAC IN is input from the control circuit 14 to the DAC 13. The DAC 13 converts the digital data DAC IN into an analog signal and outputs the analog signal obtained by the conversion in the DAC 13 to the comparator 12, as the signal V2.

The control circuit 14 comprehensively controls the operations in the main circuit 10 based on the selection signal CSB and the clock signal SCK. Specifically, the control circuit 14 controls the operation of the T/H circuit 11 through the output of the control signal CNT TH based on the selection signal CSB and the clock signal SCK. Further, the control circuit 14 decides the value of each bit of the digital data DOUT bit by bit from the most significant bit to the least significant bit by referring to the signal S_{CMP} while changing the digital data DAC IN step by step through binary search.

That is, during the period in which the T/H circuit 11 operates in the hold mode, the control circuit 14 performs the following first to N-th unit operations in this order. In the first unit operation, the signal V2 having a voltage (VDD/2) is output from the DAC 13. At this time, if the signal S_{CMP} indicates “V1>V2,” the bit value D[N] is decided to be “1.” Otherwise, the bit value D[N] is decided to be “0.” In the second unit operation when “D[N]=1” is decided, the signal V2 having a voltage of (3·VDD/4) is output from the DAC 13. At this time, if the signal S_{CMP} indicates “V1>V2,” the bit value D[N−1] is decided to be “1.” Otherwise, the bit value D[N−1] is decided to be “0.” In the second unit operation when “D[N]=0” is decided, the signal V2 having a voltage of (VDD/4) is output from the DAC 13. At this time, if the signal S_{CMP} indicates “V1>V2,” the bit value D[N−1] is decided to be “1.” Otherwise, the bit value D[N−1] is decided to be “0.” If “N=2,” the values of all bits of the digital data DOUT are decided at this stage. Since it is assumed that “N=12” in this embodiment, the third to twelfth unit operations are similarly executed, and the bit values D[9] to D[0] are decided in the third to twelfth unit operations, respectively.

The data output circuit 20 outputs the digital data DOUT from the data output terminal T_{SDO} in the form of a serial signal synchronized with the clock signal SCK during the active period. The data output circuit 20 includes a driver 21, an output-stage circuit 22 provided with transistors 22H and 22L, and protective diodes 23 and 24. In the output-stage circuit 22, the transistor 22H functions as a high-side transistor, and the transistor 22L functions as a low-side transistor. The transistor 22H is a P-channel MOSFET, and the transistor 22L is an N-channel MOSFET.

The driver 21 is connected to each of the gates of the transistors 22H and 22L. A drive control signal S_{DRV} and an output enable signal S_{EN} are supplied from the control circuit 14 to the driver 21. The driver 21 controls the turn-on/off of the transistors 22H and 22L by controlling potentials of the gates of the transistors 22H and 22L based on the signals S_{DRV} and S_{EN}.

The source of the transistor 22H is connected to a power supply wiring WR_H to which the power supply voltage IOVDD for communication is applied. The drains of the transistors 22H and 22L are connected in common to the data output terminal T_{SDO}. The source of the transistor 22L is connected to the ground. The cathode of the protective diode 23 is connected to the power supply wiring WR_H. The anode of the protective diode 23 and the cathode of the protective diode 24 are connected in common to the data output terminal T_{SDO}. The anode of the protective diode 24 is connected to the ground. The protective diodes 23 and 24 are elements for protection against static electricity and the like. A connection node between the diodes 23 and 24 is located between a connection node between the transistors 22H and 22L and the data output terminal T_{SDO}.

The output-stage circuit 22 takes one of an output high state, an output low state, and a Hi-Z state. The output high state is a state in which the transistor 22H is turned on and the transistor 22L is turned off. The output low state is a state in which the transistor 22H is turned off and the transistor 22L is turned on. The Hi-Z state is a state in which both of the transistors 22H and 22L are turned off.

The driver 21 can set the output-stage circuit 22 to the output high state by supplying a low level signal to each of the gates of the transistors 22H and 22L. The driver 21 can set the output-stage circuit 22 to the output low state by supplying a high level signal to each of the gates of the transistors 22H and 22L. The driver 21 can set the output-stage circuit 22 to the Hi-Z state by supplying a high level signal to the gate of the transistor 22H and a low level signal to the gate of the transistor 22L. The low level signal for the gates of the transistors 22H and 22L has substantially the same potential as the ground potential, and the high level signal for the gates of the transistors 22H and 22L has substantially the same potential as the potential of the power supply voltage IOVDD.

The drive control signal S_{DRV} and the output enable signal S_{EN} each have a value of “1” or “0.” FIG. 4 shows a basic relationship among the selection signal CSB, the output enable signal S_{EN}, the drive control signal S_{DRV}, and the output-stage circuit 22. The control circuit 14 sets the value of the output enable signal S_{EN} to “0” when the selection signal CSB is non-active, that is, during the non-active period. The driver 21 sets the output-stage circuit 22 to the Hi-Z state when “S_{EN}=0.” In other words, the output-stage circuit 22 is in the Hi-Z state during the non-active period. The control circuit 14 sets the value of the output enable signal S_{EN} to “1” when the selection signal CSB is active, that is, during the active period. When “S_{EN}=1” (thus during the active period), the driver 21 sets the output-stage circuit 22 to the output high state or the output low state according to the drive control signal S_{DRV}. When “S_{EN}=1,” the driver 21 sets the output-stage circuit 22 to the output high state if “S_{DRV}=1,” and sets the output-stage circuit 22 to the output low state if “S_{DRV}=0.”

The selection signal CSB itself may be the output enable signal S_{EN}, or the selection signal CSB may be directly supplied to the driver 21. In this case, it may be understood that the active selection signal CSB corresponds to the output enable signal S_{EN} having a value of “1” and the non-active selection signal CSB corresponds to the output enable signal S_{EN} having a value of “0.”

The control circuit 14 may maintain the output enable signal S_{EN} at “0” for a short period of time immediately after the selection signal CSB is switched from the high level to the low level, and then may switch the output enable signal S_{EN} to “1.” In this case, the output-stage circuit 22 can be in the Hi-Z state for a short period of time immediately after the selection signal CSB is switched from the high level to the low level. Further, the control circuit 14 may maintain the output enable signal S_{EN} at “1” for a short period of time immediately after the selection signal CSB is switched from the low level to the high level, and then may switch the output enable signal S_{EN} to “0.” In this case, the output-stage circuit 22 can be in the output high state or the output low state for a short period of time immediately after the selection signal CSB is switched from the low level to the high level.

When the output-stage circuit 22 is set to the output high state, the power supply wiring WR_H is conductive with the data output terminal T_{SDO} through the channel of the transistor 22H, so that the potential of the data signal SDO (the potential of the data output terminal T_{SDO}) has a high level. The data signal SDO of the high level has substantially the potential of the power supply voltage IOVDD. When the output-stage circuit 22 is set to the output low state, the ground is conductive with the data output terminal T_{SDO} through the channel of the transistor 22L, so the potential of the data signal SDO (the potential of the data output terminal T_{SDO}) has a low level. The data signal SDO of the low level has substantially the ground potential.

The impedance of the data output circuit 20 (in other words, the impedance of the output-stage circuit 22) seen from the data output terminal T_{SDO} is much higher when the output-stage circuit 22 is in the Hi-Z state than when the output-stage circuit 22 is in the output high state or the output low state. Therefore, assuming that the level adjustment circuit 30, which will be described later, does not operate during the non-active period in which the output-stage circuit 22 is in the Hi-Z state, the potential of the data signal SDO is maintained unchanged (while minor fluctuations are ignored).

The level adjustment circuit 30 is connected to the data output terminal T_{SDO}. The configuration and operation of the level adjustment circuit 30 will be described in detail later, and a virtual operation will be described.

### [Virtual Operation]

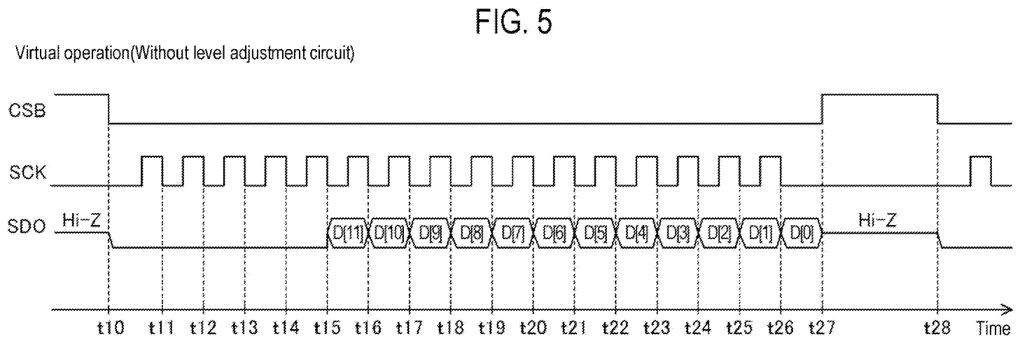

A virtual operation is an operation of the A/D converter 1 when it is assumed that the A/D converter 1 does not have the level adjustment circuit 30. FIG. 5 shows a timing chart of the A/D converter 1 in the virtual operation. It is assumed that times t10 to t28 are traversed in this order as time progresses. The selection signal CSB is maintained at a high level before time t10, and a down-edge occurs in the selection signal CSB at time t10. Thereafter, it is assumed that the selection signal CSB is maintained at a low level until just before time t27, an up-edge occurs in the selection signal CSB at time t27, and a down-edge occurs again in the selection signal CSB at time t28. Therefore, a period between times t10 and t27 is an active period, and a period between times t27 and t28 is a non-active period.

Between times t10 and t27, up-edges and down-edges repeatedly and alternately occur in the clock signal SCK. Here, the clock signal SCK has a low level at time t10, an up-edge occurs in the clock signal SCK at a time between times t10 and t11, and a first down-edge occurs in the clock signal SCK at time t11. After that, it is assumed that the second to sixteenth down-edges occur in the clock signal SCK at times t12 to t26, respectively. In the clock signal SCK, there is one up-edge between two adjacent down-edges.

The output-stage circuit 22 is in the Hi-Z state before time t10. Now, the A/D converter 1 is assumed to adopt the first output specification. When the first output specification is adopted, taking the opportunity of the down-edge of the selection signal CSB, the output-stage circuit 22 is switched from the Hi-Z state to the output low state. In order to implement this, taking the opportunity of the down-edge of the selection signal CSB, the control circuit 14 switches from “S_{EN}=0” to “S_{EN}=1” and supplies the drive control signal S_{DRV} of “0” to the driver 21. In FIG. 5, the output-stage circuit 22 is switched from the Hi-Z state to the output low state without delay after the down-edge occurs in the selection signal CSB at time t10. However, for example, the output-stage circuit 22 may be switched from the Hi-Z state to the output low state when the next down-edge of the clock signal SCK occurs (that is, at time t11) after the down-edge occurs in the selection signal CSB.

The control circuit 14 causes the T/H circuit 11 to operate in the track mode (that is, sets “CNT_{TH}=0”) until the fourth down-edge occurs in the clock signal SCK at time t14 after the down-edge occurs in the selection signal CSB at time t10. Then, taking the opportunity of the fourth down-edge of the clock signal SCK at time t14, the operation mode of the T/H circuit 11 is switched from the track mode to the hold mode (that is, is switched from “CNT_{TH}=0” to “CNT_{TH}=1”).

The A/D conversion operation by binary search is executed from time t14 to time t26, and the value of each bit of the digital data DOUT is decided bit by bit from the most significant bit to the least significant bit. In the example of FIG. 5, the first unit operation is executed starting at time t14 to decide the bit value D[11], and the bit value D[11] is output from the data output terminal T_{SDO} as the data signal SDO between times t15 and t16. Similarly, the second unit operation is executed starting at time t15 to decide the bit value D[10], and the bit value D[10] is output from the data output terminal T_{SDO} as the data signal SDO between times t16 and t17. The same applies to the third to twelfth unit operations.

In this way, after time t10, taking the opportunity of the fourth to fifteenth down-edges of the clock signal SCK, the first to twelfth unit operations are executed, respectively. The bit values D[11] to D[0] are decided by the first to twelfth unit operations, respectively. Taking the opportunity of the fifth to sixteenth down-edges of the clock signal SCK, the decided bit values D[11] to D[0] are output from the data output terminal T_{SDO}, as the data signal SDO. The data signal SDO is updated every one clock period. One clock period is a period between two adjacent down-edges in the clock signal SCK.

During a period in which the bit values D[11] to D[0] are output from the data output terminal T_{SDO}, the high-level data signal SDO represents “1” and the low-level data signal SDO represents “0.” Therefore, when the bit value D[11] is decided to be “1” by the first unit operation, the control circuit 14 supplies the drive control signal S_{DRV} of “1” to the driver 21 between times t15 and t16, thereby setting the level of the data signal SDO to a high level. Conversely, when the bit value D[11] is decided to be “0” by the first unit operation, the control circuit 14 supplies the drive control signal S_{DRV} of “0” to the driver 21 between times t15 and t16, thereby setting the level of the data signal SDO to a low level. Similarly, when the bit value D[10] is decided to be “1” by the second unit operation, the control circuit 14 supplies the drive control signal S_{DRV} of “1” to the driver 21 between times t16 and t17, thereby setting the level of the data signal SDO to a high level. Conversely, when the bit value D[10] is decided to be “0” by the second unit operation, the control circuit 14 supplies the drive control signal S DRV of “0” to the driver 21 between times t16 and t17, thereby setting the level of the data signal SDO to a low level. The same applies to the bit values D[9] to D[0].

After switching from “S_{EN}=0” to “S_{EN}=1” taking the opportunity of the down-edge of the selection signal CSB at time t10, “S_{EN}=1” is maintained until an up-edge occurs in the selection signal CSB. In the example of FIG. 5, at time t27 when an up-edge occurs in the selection signal CSB, the control circuit 14 switches from “S_{EN}=1” to “S_{EN}=0,” thereby causing the output-stage circuit 22 to be switched from the output high state or the output low state to the Hi-Z state.

### [Concerns Related to Virtual Operation]

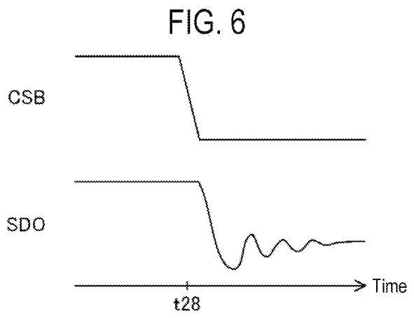

Attention is paid to signals after time t27 in the virtual operation of FIG. 5. In the virtual operation of FIG. 5, the data signal SDO of the bit value D[0] output starting at time t26 has either a high level or a low level. Since the output-stage circuit 22 is in the Hi-Z state between times t27 and t28, when the data signal SDO of the bit value D[0] is at the high level and a down-edge occurs in the selection signal CSB at time t28, with the switching of the output-stage circuit 22 from the Hi-Z state to the output low state, the data signal SDO rapidly changes from the high level to the low level in the virtual operation, as shown in FIG. 6. Such a rapid change often causes ringing in the data signal SDO (that is, the potential of the data output terminal T_{SDO}), which becomes noise for the A/D conversion operation. When this noise propagates to a wiring for applying the power supply voltage VDD, the ground wiring, or the wiring WR_AIN via a printed circuit board on which the A/D converter 1 is mounted or the inside of the A/D converter 1, the A/D conversion characteristics deteriorate.

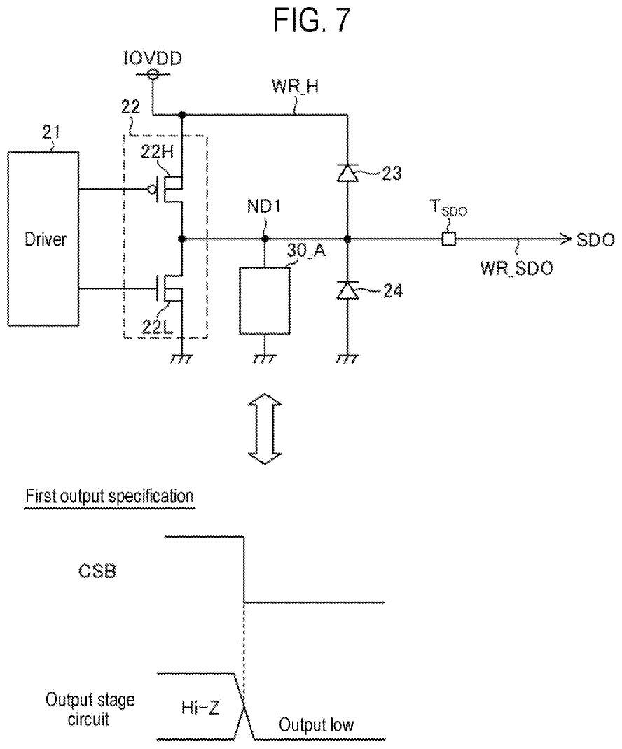

Taking this into consideration, the A/D converter 1 is provided with the level adjustment circuit 30 (see FIG. 1). When the A/D converter 1 adopts the above-mentioned first output specification, the A/D converter 1 is provided with a level adjustment circuit 30_A of FIG. 7 as the level adjustment circuit 30. The level adjustment circuit 30_A is provided between the data output terminal T_{SDO} and the ground. In a case where the data output terminal T_{SDO} is at a high level when the active period is switched to the non-active period, the level adjustment circuit 30_A extracts electric charges from the wiring WR_SDO via a resistance component during the non-active period, thereby gently lowering the signal level of the data output terminal T_{SDO} to the ground potential. The level adjustment circuit 30_A is connected between a node ND1 and the ground. The node ND1 is connected to the data output terminal T_{SDO} via a wiring inside the A/D converter 1. A connection node between the diodes 23 and 24 is located between the node ND1 and the data output terminal T_{SDO}.

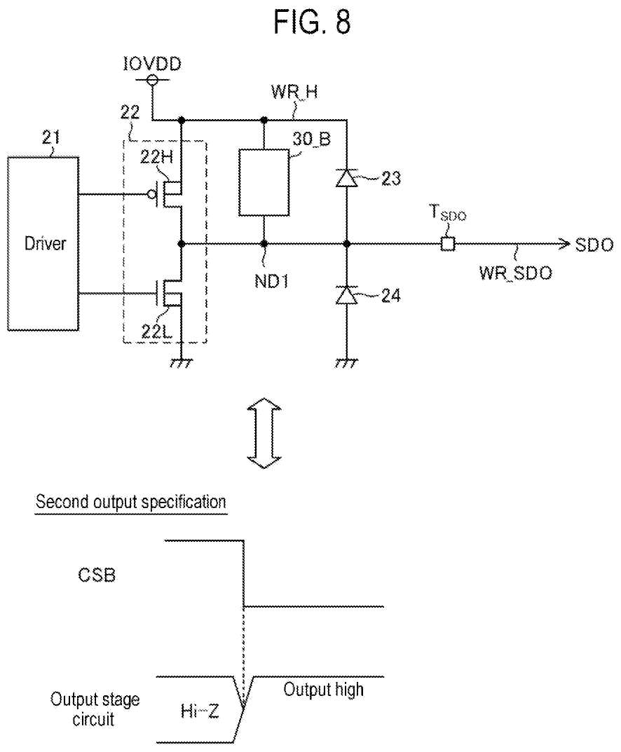

The A/D converter 1 may adopt the second output specification. When the second output specification is adopted, taking the opportunity of the down-edge of the selection signal CSB, the output-stage circuit 22 is switched from the Hi-Z state to the output high state (see FIG. 8). When the A/D converter 1 adopts the second output specification, the A/D converter 1 is provided with a level adjustment circuit 30_B of FIG. 8 as the level adjustment circuit 30. The level adjustment circuit 30_B is provided between the data output terminal T_{SDO} and the power supply wiring WR_H. In a case where the data output terminal T_{SDO} is at a low level when the active period is switched to the non-active period, the level adjustment circuit 30_B supplies electric charges from the power supply wiring WR_H to the wiring WR_SDO via a resistance component during the non-active period, thereby gently raising the signal level of the data output terminal T_{SDO} to the potential of the power supply voltage IOVDD. The level adjustment circuit 30_B is connected between the node ND1 and the power supply wiring WR_H.

Hereinafter, among a plurality of Examples, configuration examples and application techniques of the level adjustment circuit 30 will be described. Unless contradictory, the matters described in any one of the plurality of Examples shown below may also be applied to any other Examples (that is, any two or more of the plurality of Examples may be used in combination). Note that the operation of the A/D converter 1 of FIG. 1 is the same as the above-described virtual operation except that the level adjustment circuit 30 operates effectively.

### Example EX_A1

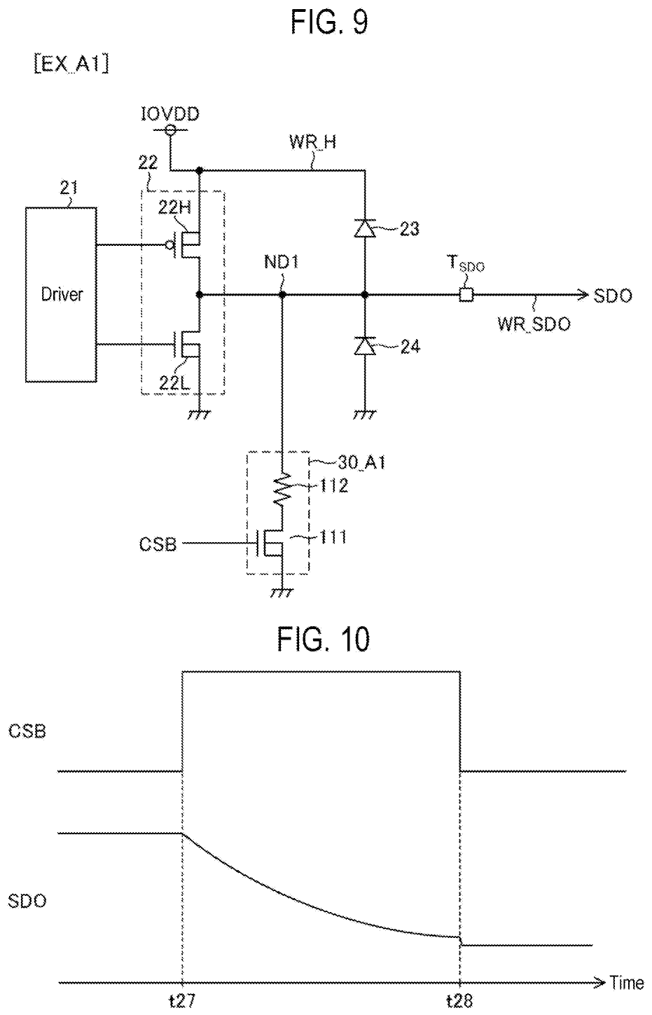

Example EX_A1 will be described. In Example EX_A1 and Examples EX_A2 and EX_A3 to be described later, the A/D converter 1 adopts the first output specification (see FIG. 7). A level adjustment circuit 30_A1 of FIG. 9 is an example of the level adjustment circuit 30_A. The level adjustment circuit 30_A1 is constituted with a series circuit of a transistor 111 and a limiting resistor 112. The transistor 111 is an N-channel MOSFET. A first end of the limiting resistor 112 is connected to the node ND1 (and therefore connected to the data output terminal T_{SDO}), and a second end of the limiting resistor 112 is connected to the drain of the transistor 111. The source of the transistor 111 is connected to the ground.

The selection signal CSB is supplied to the gate of the transistor 111. Therefore, when the selection signal CSB is active (that is, when the selection signal CSB is at a low level), the transistor 111 is turned off, and when the selection signal CSB is non-active (that is, when the selection signal CSB is at a high level), the transistor 111 is turned on. Further, the on-resistance value of the transistor 111 may be sufficiently smaller than the value of the limiting resistor 112.

When the level adjustment circuit 30_A1 is used, in a case where the signal level of the data output terminal T_{SDO} is a high level immediately before the up-edge of the selection signal CSB, as shown in FIG. 10, after the selection signal CSB switches to a high level at time t27, electric charges are drawn from the wiring WR_SDO to the ground via the data output terminal T_{SDO}, the limiting resistor 112, and the transistor 111, and the signal level of the data output terminal T_{SDO} (that is, the signal level of the data signal SDO) is gently lowered from the high level to the low level with a slope corresponding to the value of the limiting resistor 112. After that, when a down-edge occurs in the selection signal CSB at time t28, the state of the output-stage circuit 22 switches from the Hi-Z state to the output low state, but the signal level of the data output terminal T_{SDO} at that time is close to or has the ground potential.

Therefore, the above-mentioned noise (including ringing) accompanying the switching of the output-stage circuit 22 from the Hi-Z state to the output low state is suppressed, thereby improving the A/D conversion characteristics. There are harmonic distortion (THD) and signal-to-noise ratio (SNR) as indicators of the A/D conversion characteristics. Since the above-mentioned noise (see FIG. 6) results in a raised noise floor rather than harmonic distortion, the introduction of the level adjustment circuit particularly improves the SNR (the same applies to other Examples to be described later).

In the level adjustment circuit 30_A1, a series circuit of a limiting resistor and a switch is provided between the data output terminal T_{SDO} and the ground, and the transistor 111 is an example of the switch. Any switching element that is turned off when the selection signal CSB is active and is turned on when the selection signal CSB is non-active may be used as the switch in the level adjustment circuit 30_A1.

### Example EX_A2

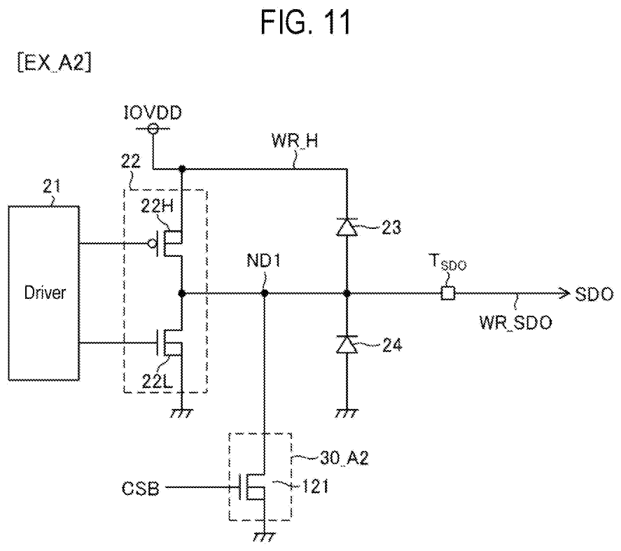

Example EX_A2 will be described. A level adjustment circuit 30_A2 of FIG. 11 is an example of the level adjustment circuit 30_A. The level adjustment circuit 30_A2 is provided with a transistor 121 which is an N-channel MOSFET. The drain of the transistor 121 is connected to the node ND1 (and therefore connected to the data output terminal T_{SDO}), and the source of the transistor 121 is connected to the ground. That is, the level adjustment circuit 30_A2 of FIG. 11 has a configuration obtained by removing the limiting resistor 112 from the level adjustment circuit 30_A1 of FIG. 9. However, the transistor 121 having a higher on-resistance than that of the transistor 111 of the level adjustment circuit 30_A1 is used, and the on-resistance of the transistor 121 functions as a limiting resistor in the level adjustment circuit 30_A2.

The selection signal CSB is supplied to the gate of the transistor 121. Therefore, when the selection signal CSB is active (that is, when the selection signal CSB is at a low level), the transistor 121 is turned off, and when the selection signal CSB is non-active (that is, when the selection signal CSB is at a high level), the transistor 121 is turned on.

When the level adjustment circuit 30_A2 is used, in a case where the signal level of the data output terminal T_{SDO} is a high level immediately before the up-edge of the selection signal CSB, as shown in FIG. 10, after the selection signal CSB switches to a high level at time t27, electric charges are drawn from the wiring WR_SDO to the ground via the data output terminal T_{SDO} and the transistor 121, and the signal level of the data output terminal T_{SDO} (that is, the signal level of the data signal SDO) is gently lowered from the high level to the low level with a slope corresponding to the on-resistance value of the transistor 121. After that, when a down-edge occurs in the selection signal CSB at time t28, the state of the output-stage circuit 22 switches from the Hi-Z state to the output low state, but the signal level of the data output terminal T_{SDO} at that time is close to or has the ground potential.

Therefore, the level adjustment circuit 30_A2 may also provide the same effects as the level adjustment circuit 30_A1. The transistor 121 is an example of a switch in the level adjustment circuit 30_A2. Any switching element that is turned off when the selection signal CSB is active and is turned on when the selection signal CSB is non-active may be used as the switch in the level adjustment circuit 30_A2.

### Example EX_A3

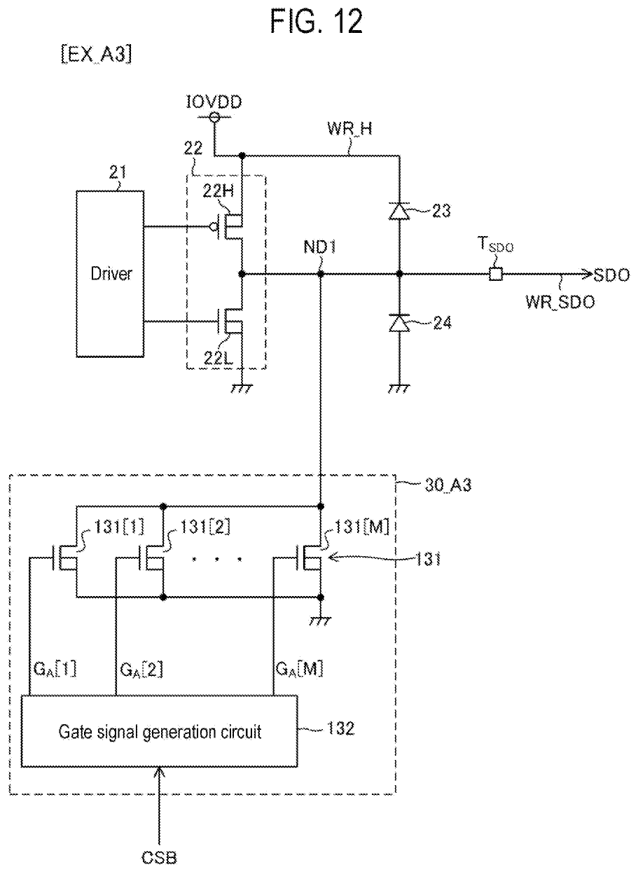

Example EX_A3 will be described. A level adjustment circuit 30_A3 of FIG. 12 is an example of the level adjustment circuit 30_A. The level adjustment circuit 30_A3 includes a transistor group 131 and a gate signal generation circuit 132. The transistor group 131 includes M transistors 131[1] to 131[M] connected in parallel. M is any integer of 2 or more. The transistors 131[1] to 131[M] are N-channel MOSFETs. The drains of the transistors 131[1] to 131[M] are connected in common to the node ND1 (and therefore connected to the data output terminal T_{SDO}). The sources of the transistors 131[1] to 131[M] are connected to the ground.

Here, the on-resistance of a transistor 131[j] is smaller than that of a transistor 131[j+1]. j represents an arbitrary integer.

The gate signal generation circuit 132 generates gate signals G_{A}[1] to G_{A}[M] according to the selection signal CSB and supplies the gate signals G_{A}[1] to G_{A}[M] to the transistors 131[1] to 131[M], respectively, so that the transistors 131[1] to 131[M] are individually controlled to be turned on or off. When a gate signal G_{A}[j] is at a high level, the transistor 131[j] is turned on. When the gate signal G_{A}[j] is at a low level, the transistor 131[j] is turned off.

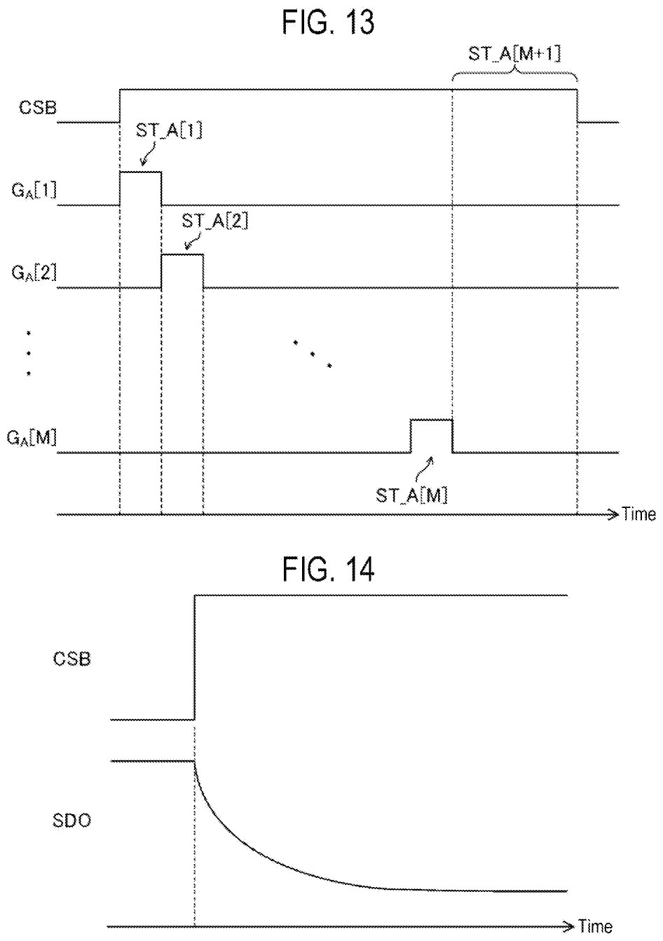

FIG. 13 shows a relationship between the selection signal CSB and the gate signals G_{A}[1] to G_{A}[M]. When the selection signal CSB is active, that is, when the selection signal CSB is at a low level, the gate signal generation circuit 132 sets all of the gate signals G_{A}[1] to G_{A}[M] to a low level so that the transistors 131[1] to 131[M] are all kept off.

When an up-edge occurs in the selection signal CSB, the gate signal generation circuit 132 switches the state of the transistor group 131 between states ST_A[1] to ST_A[M+1]. Under the condition that “1M” is satisfied, in a state ST_A[j], only the gate signal G_{A}[j] among the gate signals G_{A}[1] to G_{A}[M] is set to a high level, and as a result, only the transistor 131[j] among the transistors 131[1] to 131[M] is turned on. In the state ST_A[M+1], the gate signals G_{A}[1] to G_{A}[M] are all set to a low level so that the transistors 131[1] to 131[M] are all turned off.

When the up-edge occurs in the selection signal CSB, the gate signal generation circuit 132 executes the following state transition sequence SEQ_{A}. In the state transition sequence SEQ_{A}, the gate signal generation circuit 132 first sets the state of the transistor group 131 to the state ST_A[1] and then switches the state of the transistor group 131 sequentially from the state ST_A[1] to the state ST_A[2], ST_A[3], . . . , and ST_A[M] each time a predetermined period of time elapses. After the predetermined period of time has elapsed since the state of the transistor group 131 was switched to the state ST_A[M], the gate signal generation circuit 132 switches the state of the transistor group 131 to the state ST_A[M+1] and, thereafter, keeps the state of the transistor group 131 in the state ST_A[M+1] until a down-edge occurs in the selection signal CSB. When the down-edge occurs in the selection signal CSB after the up-edge occurs in the selection signal CSB and before the state of the transistor group 131 is set to the state ST_A[M+1], the gate signal generation circuit 132 immediately stops the state transition sequence SEQ_{A} and turns off all the transistors 131[1] to 131[M].

By using the level adjustment circuit 30_A3, when the signal level of the data output terminal T_{SDO} is a high level immediately before the up-edge of the selection signal CSB, the state transition sequence SEQ_{A} is executed after the selection signal CSB is switched to a high level at time t27, thereby obtaining a signal waveform similar to that in FIG. 10. In the process of the state transition sequence SEQ_{A}, electric charges are drawn from the wiring WR_SDO to the ground via the data output terminal T_{SDO} and one of the transistors in the transistor group 131, and the signal level of the data output terminal T_{SDO} (that is, the signal level of the data signal SDO) is gently lowered from the high level to the low level with a slope corresponding to the resistance value of the transistor group 131. After that, when a down-edge occurs in the selection signal CSB at time t28, the state of the output-stage circuit 22 switches from the Hi-Z state to the output low state, but the signal level of the data output terminal T_{SDO} at that time is close to or has the ground potential.

Therefore, the level adjustment circuit 30_A3 can also provide the same effects as the level adjustment circuit 30_A1. Further, as described above, the on-resistance of the transistor 131[j] is smaller than that of the transistor 131[j+1]. Therefore, the resistance value of the transistor group 131 increases step by step until the transistor group 131 reaches the state ST_A[M+1] in the state transition sequence SEQ_{A}. Here, the resistance value of the transistor group 131 is a resistance value between the node ND1 and the ground, and refers to the on-resistance value of a transistor that is turned on among the transistors 131[1] to 131[M].

By increasing the resistance value of the transistor group 131 step by step in the state transition sequence SEQ_{A}, the potential of the data output terminal T_{SDO} is decreased with a relatively large slope immediately after the up-edge of the selection signal CSB, as shown in FIG. 14, and the slope of the decrease can be gradually moderated over time.

By sufficiently increasing the on-resistance of the transistor 121 in the level adjustment circuit 30_A2 of FIG. 11, the slope of the potential change of the data output terminal T_{SDO} during the high level period of the selection signal CSB can be suppressed to be sufficiently small. However, if the on-resistance of the transistor 121 is made too large while the length of the high level period of the selection signal CSB is limited, in a state where the potential of the data output terminal T_{SDO} hardly drops, the output-stage circuit 22 may be switched to the low output state at the down-edge of the selection signal CSB. In contrast, with the level adjustment circuit 30_A3 according to this Example, when the signal level of the data output terminal T_{SDO} is a high level immediately before the up-edge of the selection signal CSB, the potential of the data output terminal T_{SDO} can be greatly decreased with such a slope that does not cause the above-mentioned ringing immediately after the up-edge of the selection signal CSB. After that, the slope of the decrease is gradually made to be gentle. As a result, the above-mentioned noise (including ringing) accompanying the switching of the output-stage circuit 22 from the Hi-Z state to the output low state is suppressed as much as possible, thereby improving the A/D conversion characteristics.

The level adjustment circuit 30_A3 of FIG. 12 may be modified so that the transistors 131[1] to 131[M] have the same sufficiently small on-resistance. However, in this modification, one limiting resistor (not shown) is provided between each of the drains of the transistors 131[1] to 131[M] and the node ND1. That is, in this modification, a first limiting resistor is provided between the drain of the transistor 131[1] and the node ND1, a second limiting resistor is provided between the drain of the transistor 131[2] and the node ND1, . . . , and an M-th limiting resistor is provided between the drain of the transistor 131[M] and the node ND1. At this time, it is preferable to set the value of each limiting resistor such that the value of a j-th limiting resistor is smaller than the value of a (j+1)-th limiting resistor. As a result, an effect equivalent to that of the level adjustment circuit 30_A3 before modification can be obtained.

Here, a description of the level adjustment circuits 30_A (30_A1, 30_A2, 30_A3) is added. In a case where the signal level (SDO) of the data output terminal T_{SDO} has a high level when switching from the active period to the non-active period, the level adjustment circuit 30_A changes the signal level (SDO) of the data output terminal T_{SDO} from the high level to the low level after switching to the non-active period.

To implement this, the level adjustment circuit 30_A (30_A1, 30_A2, 30_A3) connects the data output terminal T_{SDO} to the ground via a resistance component during the non-active period.

In the level adjustment circuit 30_A1 or 30_A2, a switch is provided between the data output terminal T_{SDO} and the ground, and the switch is turned off and on during the active period and the non-active period, respectively. By turning on the switch, the data output terminal T_{SDO} and the ground are connected to each other through an electrical path including the resistance component. Here, the electrical path is an electrical path that is provided in the level adjustment circuit 30_A1 or 30_A2 (an electrical path between the node ND1 and the ground) and includes the series circuit of the transistor 111 used as the switch and the limiting resistor 112, or the transistor 121 used as the switch with significant on-resistance.

On the other hand, in the level adjustment circuit 30_A3, the value of the above-mentioned resistance component is increased step by step along with the lapse of time after switching from the active period to the non-active period. Regarding the configuration of FIG. 12, the resistance component corresponds to the on-resistance of the transistor 131[j] in the state ST_A[j].

### Example EX_B1

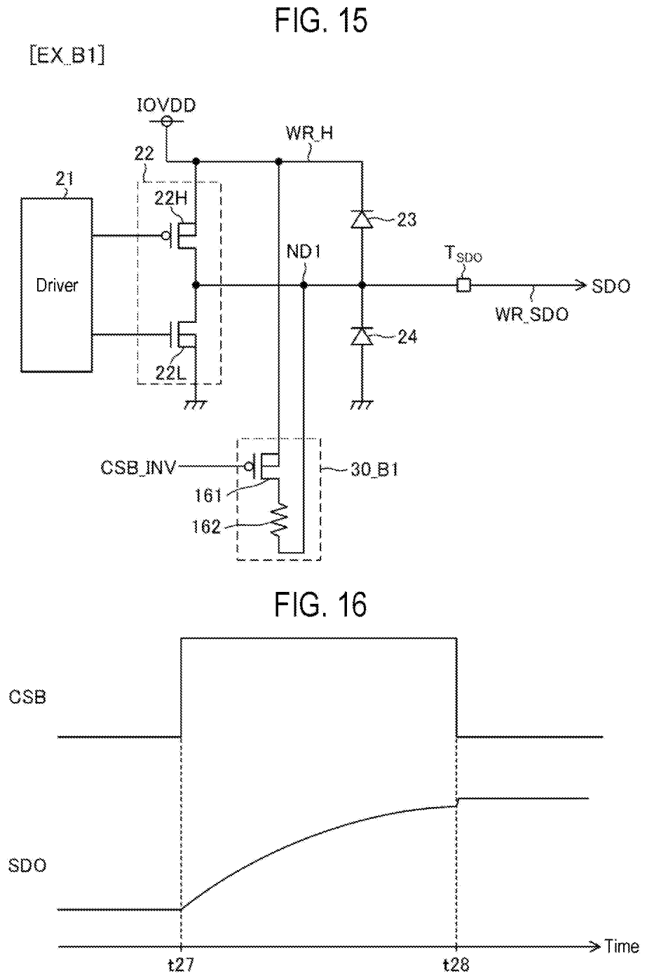

Example EX_B1 will be described. In Example EX_B1 and Examples EX_B2 and EX_B3 to be described later, the A/D converter 1 adopts the second output specification (see FIG. 8). A level adjustment circuit 30_B1 of FIG. 15 is an example of the level adjustment circuit 30_B. The level adjustment circuit 30_B1 is provided with a series circuit of a transistor 161 and a limiting resistor 162. The transistor 161 is a P-channel MOSFET. The source of the transistor 161 is connected to the power supply wiring WR_H. The drain of the transistor 161 is connected to the node ND1 via the limiting resistor 162 (and therefore connected to the data output terminal T_{SDO}).

An inverted selection signal CSB_INV is supplied to the gate of the transistor 161. The inverted selection signal CSB_INV has a high level (that is, the potential of the power supply voltage IOVDD) when the selection signal CSB is at a low level, and has a low level (that is, the ground potential) when the selection signal CSB is at a high level. Therefore, the transistor 161 is turned off when the selection signal CSB is active (that is, when the selection signal CSB is at the low level), and is turned on when the selection signal CSB is non-active (that is, when the selection signal CSB is at the high level). Further, the on-resistance value of the transistor 161 may be sufficiently smaller than the value of the limiting resistor 162.

By using the level adjustment circuit 30_B1, when the signal level of the data output terminal T_{SDO} is a low level immediately before the up-edge of the selection signal CSB, as shown in FIG. 16, after the selection signal CSB switches to high level at time t27, electric charges are supplied from the power supply wiring WR_H to the wiring WR_SDO via the transistor 161, the limiting resistor 162, and the data output terminal T_{SDO}, and the signal level of the data output terminal T_{SDO} (that is, the signal level of the data signal SDO) gently rises from the low level to the high level with a slope corresponding to the value of the limiting resistor 162. After that, when a down-edge occurs in the selection signal CSB at time t28, the state of the output-stage circuit 22 switches from the Hi-Z state to the output high state, but the signal level of the data output terminal T_{SDO} at that time is close to or has the potential of the power supply voltage IOVDD.

Therefore, the above-mentioned noise (including ringing) accompanying the switching from the Hi-Z state to the output high state of the output-stage circuit 22 can be suppressed, thereby improving the A/D conversion characteristics.

In the level adjustment circuit 30_B1, a series circuit of a limiting resistor and a switch is provided between the data output terminal T_{SDO} and the power supply wiring WR_H, and the transistor 161 is an example of the switch. Any switching element that is turned off when the selection signal CSB is active and is turned on when the selection signal CSB is non-active may be used as the switch in the level adjustment circuit 30_B1.

### Example EX_B2

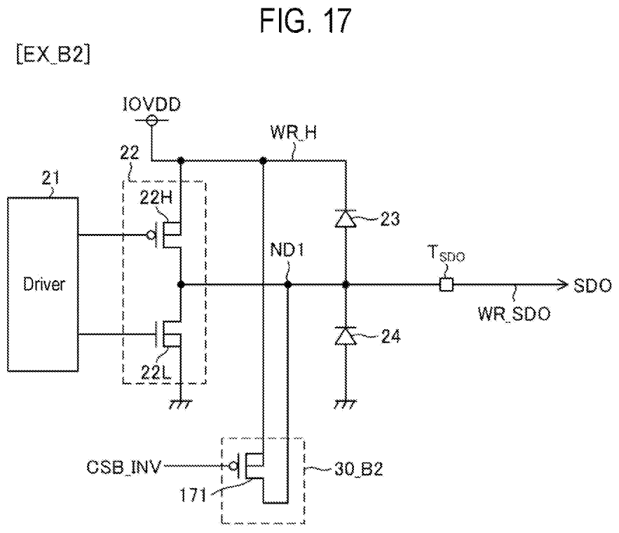

Example EX_B2 will be described. A level adjustment circuit 30_B2 of FIG. 17 is an example of the level adjustment circuit 30_B. The level adjustment circuit 30_B2 is provided with a transistor 171 which is a P-channel MOSFET. The source of the transistor 171 is connected to the power supply wiring WR_H, and the drain of the transistor 171 is connected to the node ND1 (and therefore connected to the data output terminal T_{SDO}). That is, the level adjustment circuit 30_B2 of FIG. 17 has a configuration obtained by removing the limiting resistor 162 from the level adjustment circuit 30_B1 of FIG. 15. However, the transistor 171 having a higher on-resistance than that of the transistor 161 of the level adjustment circuit 30_B1 is used, and the on-resistance of the transistor 171 functions as a limiting resistor in the level adjustment circuit 30_B2.

An inverted selection signal CSB_INV is supplied to the gate of the transistor 171. Therefore, the transistor 171 is turned off when the selection signal CSB is active (that is, when the selection signal CSB is at a low level), and is turned on when the selection signal CSB is non-active (that is, when the selection signal CSB is at a high level).

By using the level adjustment circuit 30_B2, when the signal level of the data output terminal T_{SDO} is a low level immediately before the up-edge of the selection signal CSB, as shown in FIG. 16, after the selection signal CSB switches to a high level at time t27, electric charges are supplied from the power supply wiring WR_H to the wiring WR_SDO via the transistor 171 and the data output terminal T_{SDO}, and the signal level of the data output terminal T_{SDO} (that is, the signal level of the data signal SDO) gently rises from the low level to the high level with a slope corresponding to the on-resistance value of the transistor 171. After that, when a down-edge occurs in the selection signal CSB at time t28, the state of the output-stage circuit 22 switches from the Hi-Z state to the output high state, but the signal level of the data output terminal T_{SDO} at that time is close to or has the potential of the power supply voltage IOVDD.

Therefore, the level adjustment circuit 30_B2 can also provide the same effects as the level adjustment circuit 30_B1. The transistor 171 is an example of a switch in the level adjustment circuit 30_B2. Any switching element that is turned off when the selection signal CSB is active and is turned on when the selection signal CSB is non-active may be used as the switch in the level adjustment circuit 30_B2.

### Example EX_B3

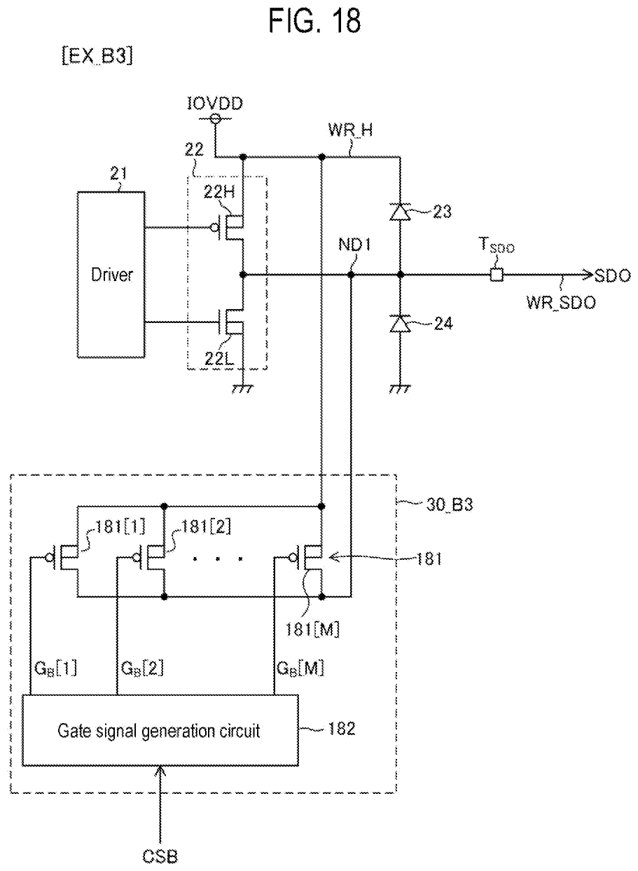

Example EX_B3 will be described. A level adjustment circuit 30_B3 of FIG. 18 is an example of the level adjustment circuit 30_B. The level adjustment circuit 30_B3 has a transistor group 181 and a gate signal generation circuit 182. The transistor group 181 includes M transistors 181[1] to 181[M] connected in parallel. M is any integer of 2 or more. The transistors 181[1] to 181[M] are P-channel MOSFETs. The sources of the transistors 181[1] to 181[M] are connected in common to the power supply wiring WR_H, and the drains of the transistors 181[1] to 181[M] are connected in common to the node ND1 (and therefore connected to the data output terminal T_{SDO}).

Here, the on-resistance of a transistor 181[j] is smaller than that of a transistor 181[j+1]. j represents any natural number.

The gate signal generation circuit 182 generates gate signals G_{B}[1] to G_{B}[M] according to the selection signal CSB and supplies the gate signals G_{B}[1] to G_{B}[M] to the transistors 181[1] to 181[M], respectively, so that the transistors 181[1] to 181[M] are individually controlled to be turned on or off. When a gate signal G_{B}[j] is at a high level, the transistor 181[j] is turned on. When the gate signal G_{B}[j] is at a low level, the transistor 181[j] is turned off.

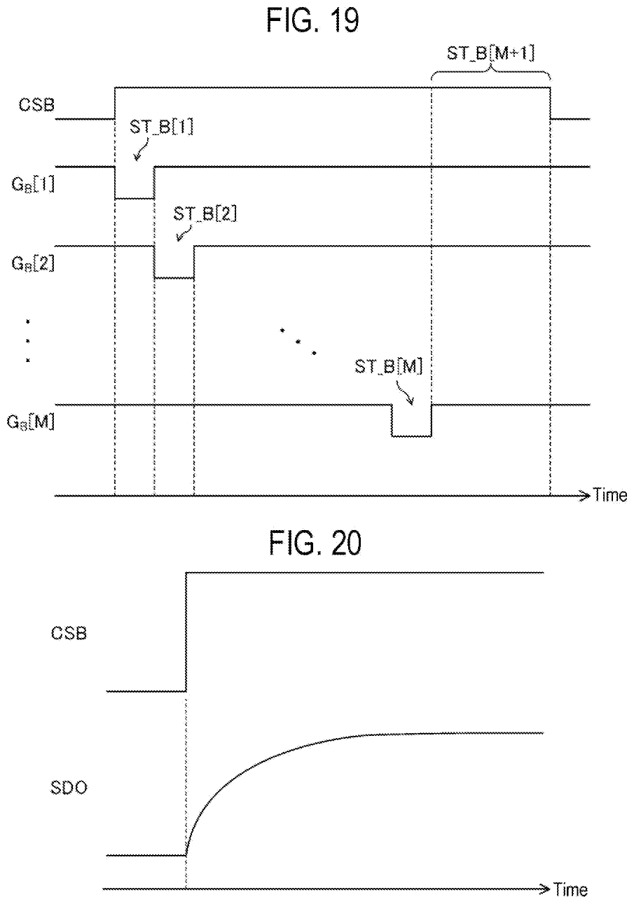

FIG. 19 shows a relationship between the selection signal CSB and the gate signals G_{B}[1] to G_{B}[M]. When the selection signal CSB is active, that is, when the selection signal CSB is at a low level, the gate signal generation circuit 182 sets all of the gate signals G_{B}[1] to G_{B}[M] to a high level so that the transistors 181[1] to 181[M] are all kept off.

When an up-edge occurs in the selection signal CSB, the gate signal generation circuit 182 switches the state of the transistor group 181 between states ST_B[1] to ST_B[M+1]. Under the condition that “1M” is satisfied, in a state ST_B[j], only the gate signal G_{B}[j] among the gate signals G_{B}[1] to G_{B}[M] is set to a high level, and as a result, only the transistor 181[j] among the transistors 181[1] to 181[M] is turned on. In the state ST_B[M+1], the gate signals G_{B}[1] to G_{B}[M] are all set to a high level so that the transistors 181[1] to 181[M] are all turned off.

When the up-edge occurs in the selection signal CSB, the gate signal generation circuit 182 executes the following state transition sequence SEQ_{B}. In the state transition sequence SEQ_{B}, the gate signal generation circuit 182 first sets the state of the transistor group 181 to the state ST_B [1] and then switches the state of the transistor group 181 sequentially from the state ST_B[1] to the state ST_B[2], ST_B[3], . . . , and ST_B[M] each time a predetermined period of time elapses. After the predetermined period of time has elapsed since the state of the transistor group 181 was switched to the state ST_B [M], the gate signal generation circuit 182 switches the state of the transistor group 181 to the state ST_B[M+1] and, thereafter, keeps the state of the transistor group 181 in the state ST_B[M+1] until a down-edge occurs in the selection signal CSB. When the down-edge occurs in the selection signal CSB after the up-edge occurs in the selection signal CSB and before the state of the transistor group 181 is set to the state ST_B[M+1], the gate signal generation circuit 182 immediately stops the state transition sequence SEQ_{B} and turns off all the transistors 181[1] to 181[M].

By using the level adjustment circuit 30_B3, when the signal level of the data output terminal T_{SDO} is a low level immediately before the up-edge of the selection signal CSB, the state transition sequence SEQ_{B} is executed after the selection signal CSB is switched to a high level at time t27, thereby obtaining a signal waveform similar to that in FIG. 16. In the process of the state transition sequence SEQ_{B}, electric charges are supplied from the power supply wiring WR_H to the wiring WR_SDO via one of the transistors in the transistor group 181, and the signal level of the data output terminal T_{SDO} (that is, the signal level of the data signal SDO) gently rises from the low level to the high level with a slope corresponding to the resistance value of the transistor group 131. After that, when a down-edge occurs in the selection signal CSB at time t28, the state of the output-stage circuit 22 switches from the Hi-Z state to the output high state, but the signal level of the data output terminal T_{SDO} at that time is close to or has the potential of the power supply voltage IOVDD.

Therefore, the level adjustment circuit 30_B3 can also provide the same effects as the level adjustment circuit 30_B1. Further, as described above, the on-resistance of the transistor 181[j] is smaller than that of the transistor 181[j+1]. Therefore, the resistance value of the transistor group 181 increases step by step until the transistor group 181 reaches the state ST_B[M+1] in the state transition sequence SEQ_{B}. Here, the resistance value of the transistor group 181 is a resistance value between the node ND1 and the power supply wiring WR_H, and refers to the on-resistance value of a transistor that is turned on among the transistors 181[1] to 181[M].

By increasing the resistance value of the transistor group 181 step by step in the state transition sequence SEQ_{B}, as shown in FIG. 20, the potential of the data output terminal T_{SDO} is increased with a relatively large slope immediately after the up-edge of the selection signal CSB, and the slope of the increase may be gradually moderated over time.

The level adjustment circuit 30_B3 of FIG. 18 may be modified so that the transistors 181[1] to 181[M] have the same sufficiently small on-resistance. However, in this modification, one limiting resistor (not shown) is provided between each of the drains of the transistors 181[1] to 181[M] and the node ND1. That is, in this modification, a first limiting resistor is provided between the drain of the transistor 181[1] and the node ND1, a second limiting resistor is provided between the drain of the transistor 181[2] and the node ND1, . . . , and an M-th limiting resistor is provided between the drain of the transistor 181[M] and the node ND1. At this time, it is preferable to set the value of each limiting resistor such that the value of a j-th limiting resistor is smaller than the value of a (j+1)-th limiting resistor. As a result, an effect equivalent to that of the level adjustment circuit 30_B3 before modification can be obtained.

Here, a description of the level adjustment circuits 30_B (30_B1, 30_B2, 30_B3) is added. When the signal level (SDO) of the data output terminal T_{SDO} has a low level when switching from the active period to the non-active period, the level adjustment circuit 30_B changes the signal level (SDO) of the data output terminal T_{SDO} from the low level to the high level after switching to the non-active period.

To implement this, the level adjustment circuit 30_B (30_B1, 30_B2, 30_B3) connects the data output terminal T_{SDO} to the power supply wiring WR_H via a resistance component during the non-active period.

In the level adjustment circuit 30_B1 or 30_B2, a switch is provided between the data output terminal T_{SDO} and the power supply wiring WR_H, and the switch is turned off and on during the active period and the non-active period, respectively. By turning on the switch, the data output terminal T_{SDO} and the power supply wiring WR_H are connected to each other through an electrical path including the resistance component. Here, the electrical path is an electrical path that is provided in the level adjustment circuit 30_B1 or 30_B2 (an electrical path between the node ND1 and the power supply wiring WR_H) and includes the series circuit of the transistor 161 used as the switch and the limiting resistor 162, or the transistor 171 used as the switch with significant on-resistance.

On the other hand, in the level adjustment circuit 30_B3, the value of the above-mentioned resistance component is increased step by step with the lapse of time after switching from the active period to the non-active period. Regarding the configuration of FIG. 18, the resistance component corresponds to the on-resistance of the transistor 181[j] in the state ST_B[j].

### Example EX_C

Example EX_C will be described. In Example EX_C, modified techniques or supplementary matters for each of the above matters are shown.

For any signal or voltage, its high level/low level relationship may be reversed from those described above without departing from the spirit of the above discussion. Therefore, for example, the active level of the selection signal CSB may be a high level and the non-active level of the selection signal CSB may be a low level.

As long as the A/D converter 1 according to the present disclosure is a successive-approximation type A/D conversion circuit, the internal configuration of the A/D converter 1 may be changed in various ways. Therefore, for example, the A/D converter 1 may be configured to perform A/D conversion using a capacitor-type DAC having a capacitor array and a switch array.

Any of the transistors described above may be any type of transistor as long as it does not cause any matter. For example, any transistor described above as a MOSFET may be replaced with a junction FET, an IGBT (Insulated Gate Bipolar Transistor), or a bipolar transistor as long as it does not cause any matter. Any transistor includes a first electrode, a second electrode, and a control electrode. In the FET, one of the first and second electrodes is the drain, the other is the source, and the control electrode is the gate. In the IGBT, one of the first and second electrodes is the collector, the other is the emitter, and the control electrode is the gate. In the bipolar transistor not belonging to the IGBT, one of the first and second electrodes is the collector, the other is the emitter, and the control electrode is the base.

The embodiments of the present disclosure may be appropriately modified in various ways within the scope of the technical ideas indicated in the claims. The above embodiments are merely examples of the embodiments of the present disclosure, and the meanings of the terms of the present disclosure and each constituent element are not limited to those described in the above embodiments. The specific numerical values given in the above description are merely examples and may, of course, be changed to various numerical values.

### <<Supplementary Notes>>

Supplementary Notes are provided for the present disclosure in which specific configuration examples are shown in the above-described embodiments.

A successive-approximation type A/D conversion circuit according to one aspect of the present disclosure is a successive-approximation type A/D conversion circuit 1 that converts an analog signal (AIN) into digital data (DOUT). The successive-approximation type A/D conversion circuit 1 includes: a selection signal input terminal T_{CSB} configured to receive an active or non-active selection signal CSB; a clock input terminal T_{SCK} configured to receive a clock signal SCK; a main circuit 10 configured to generate the digital data in synchronization with the clock signal during an active period in which the selection signal is active; a data output terminal T_{SDO}; a data output circuit 20 configured to output the digital data as a serial signal synchronized with the clock signal from the data output terminal during the active period; and a level adjustment circuit 30, and has a configuration (first configuration) in which the data output circuit outputs the serial signal by setting a signal level of the data output terminal to a first level (low level or high level) in response to switching of the selection signal from non-active to active and then setting the signal level of the data output terminal to the first level or a second level (high level or low level) during the active period, and when the signal level of the data output terminal has the second level at the time of switching from the active period to a non-active period in which the selection signal is non-active, the level adjustment circuit changes the signal level of the data output terminal from the second level to the first level after switching to the non-active period.

The signal level of the data output terminal may have the second level (for example, high level) immediately before the selection signal is switched from active to non-active. After that, when the signal level of the data output terminal has the second level immediately before the selection signal is switched to active again, the signal level of the data output terminal may be suddenly changed to the first level (for example, low level) with the switching of the selection signal to active, which may cause noise. In the successive-approximation type A/D conversion circuit according to the above configuration, the signal level of the data output terminal can be brought to the first level during the non-active period by the level adjustment circuit, which suppresses the noise and improves the A/D conversion characteristics.

The successive-approximation type A/D conversion circuit of the first configuration may have a configuration (second configuration) that the first level corresponds to a potential of a ground and the second level corresponds to a potential of a power supply voltage higher than the first level, and that the level adjustment circuit connects the data output terminal to the ground via a resistance component (for example, the limiting resistor 112 in FIG. 9) during the non-active period.

As a result, the signal level of the data output terminal can be gently brought to the first level during the non-active period. Suppression of the sudden change in the signal level contributes to noise reduction.

The successive-approximation type A/D conversion circuit (see FIGS. 9 and 11) according to the second configuration may have a configuration (third configuration) that the level adjustment circuit has a switch (the transistor 111 or 121) provided between the data output terminal and the ground, sets the switch to be turned off during the active period, and sets the switch to be turned on during the non-active period, and that the data output terminal and the ground are connected to each other through an electrical path including the resistance component when the switch is turned on.

The successive-approximation type A/D conversion circuit (see FIG. 12) according to the second configuration may have a configuration (fourth configuration) that the level adjustment circuit increases a value of the resistance component step by step with the lapse of time after switching from the active period to the non-active period.

This further enhances the effect of suppressing the noise.

The successive-approximation type A/D conversion circuit according to the first configuration may have a configuration (fifth configuration) that the second level corresponds to a ground potential and the first level corresponds to a potential of a power supply voltage higher than the second level, and that the level adjustment circuit connects the data output terminal to a power supply wiring to which the power supply voltage is applied, via a resistance component (for example, the limiting resistor 162 in FIG. 15) during the non-active period.

With this configuration, the signal level of the data output terminal can be gently brought to the first level during the non-active period. Suppression of a sudden change in the signal level contributes to noise reduction.

The successive-approximation type A/D conversion circuit (see FIGS. 15 and 17) according to the fifth configuration may have a configuration (sixth configuration) that the level adjustment circuit has a switch (the transistor 161 or 171) provided between the data output terminal and the power supply wiring, sets the switch to be turned off during the active period, and sets the switch to be turned on during the non-active period, and that the data output terminal and the power supply wiring are connected to each other through an electrical path including the resistance component when the switch is turned on.

The successive-approximation type A/D conversion circuit (see FIG. 18) according to the fifth configuration may have a configuration (seventh configuration) that the level adjustment circuit increases a value of the resistance component step by step with the lapse of time after switching from the active period to the non-active period.

This further enhances the effect of suppressing the noise.

The successive-approximation type A/D conversion circuit according to any one of the first to seventh configurations may have a configuration (eighth configuration) that an impedance of the data output circuit viewed from the data output terminal is higher in the non-active period than in the active period.

The successive-approximation type A/D conversion circuit according to any one of the second to eighth configurations may have a configuration (ninth configuration) that the data output circuit is provided with the output-stage circuit 22 including the high-side transistor 22H and the low-side transistor 22L connected in series with each other, that the power supply voltage is applied to a first electrode of the high-side transistor, a second electrode of the high-side transistor and a first electrode of the low-side transistor are connected to the data output terminal, and a second electrode of the low-side transistor is connected to the ground, and that the data output circuit sets the signal level of the data output terminal to the first level by turning on one of the high-side transistor and the low-side transistor and sets the signal level of the data output terminal to the second level by turning on the other of the high-side transistor and the low-side transistor, during the active period, and sets both the high-side transistor and the low-side transistor to be turned off during the non-active period.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A successive-approximation type A/D conversion circuit that converts an analog signal into digital data, comprising:
a selection signal input terminal configured to receive a selection signal which is active or non-active;
a clock input terminal configured to receive a clock signal;
a main circuit configured to generate the digital data in synchronization with the clock signal during an active period in which the selection signal is active;
a data output terminal;
a data output circuit configured to output the digital data as a serial signal synchronized with the clock signal from the data output terminal during the active period; and
a level adjustment circuit,
wherein the data output circuit outputs the serial signal by setting a signal level of the data output terminal to a first level in response to switching of the selection signal from the non-active to the active and subsequently, setting the signal level of the data output terminal to the first level or a second level during the active period, and
wherein when the signal level of the data output terminal has the second level at a time of switching from the active period to a non-active period in which the selection signal is non-active, the level adjustment circuit changes the signal level of the data output terminal from the second level to the first level after switching to the non-active period.

2. The successive-approximation type A/D conversion circuit of claim 1, wherein the first level corresponds to a potential of a ground, and the second level corresponds to a potential of a power supply voltage higher than the first level, and
wherein the level adjustment circuit connects the data output terminal to the ground via a resistance component during the non-active period.

3. The successive-approximation type A/D conversion circuit of claim 2, wherein the level adjustment circuit includes a switch provided between the data output terminal and the ground, sets the switch to be turned off during the active period, and sets the switch to be turned on during the non-active period, and
wherein the data output terminal and the ground are connected to each other through an electrical path including the resistance component when the switch is turned on.

4. The successive-approximation type A/D conversion circuit of claim 2, wherein the level adjustment circuit increases a value of the resistance component step by step with a lapse of time after switching from the active period to the non-active period.

5. The successive-approximation type A/D conversion circuit of claim 1, wherein the second level corresponds to a ground potential, and the first level corresponds to a potential of a power supply voltage higher than the second level, and
wherein the level adjustment circuit connects the data output terminal to a power supply wiring to which the power supply voltage is applied, via a resistance component during the non-active period.

6. The successive-approximation type A/D conversion circuit of claim 5, wherein the level adjustment circuit includes a switch provided between the data output terminal and the power supply wiring, sets the switch to be turned off during the active period, and sets the switch to be turned on during the non-active period, and
wherein the data output terminal and the power supply wiring are connected to each other through an electrical path including the resistance component when the switch is turned on.

7. The successive-approximation type A/D conversion circuit of claim 5, wherein the level adjustment circuit increases a value of the resistance component step by step with a lapse of time after switching from the active period to the non-active period.

8. The successive-approximation type A/D conversion circuit of claim 1, wherein an impedance of the data output circuit viewed from the data output terminal is higher in the non-active period than in the active period.

9. The successive-approximation type A/D conversion circuit of claim 2, wherein the data output circuit is provided with an output-stage circuit including a high-side transistor and a low-side transistor which are connected in series with each other,
wherein the power supply voltage is applied to a first electrode of the high-side transistor, a second electrode of the high-side transistor and a first electrode of the low-side transistor are connected to the data output terminal, and a second electrode of the low-side transistor is connected to the ground, and
wherein the data output circuit sets the signal level of the data output terminal to the first level by turning on one of the high-side transistor and the low-side transistor and sets the signal level of the data output terminal to the second level by turning on the other of the high-side transistor and the low-side transistor, during the active period, and sets both the high-side transistor and the low-side transistor to be turned off during the non-active period.
